(19) United States
(12) Patent Application Publication
(10) Pub. No.: US 2021/0399266 A1
(43) Pub. Date: Dec. 23, 2021

(54) DISPLAY DEVICE AND METHOD OF MANUFACTURING THE SAME

(71) Applicant: Samsung Display Co., LTD., Yongin-si (KR)

(72) Inventors: KYUNGHEE LEE, Suwon-si (KR); MIHWA LEE, Seoul (KR)

(73) Assignee: Samsung Display Co., LTD., Yongin-si (KR)

(21) Appl. No.: 17/186,701

(22) Filed: Feb. 26, 2021

(30) Foreign Application Priority Data
Jun. 18, 2020 (KR) 10-2020-0074359

(51) Int. Cl. H01L 51/52; H01L 27/32

(52) U.S. Cl. CPC H01L 51/5284; H01L 2251/5338; H01L 27/322

(57) ABSTRACT

A display device may include a display panel, a light control layer disposed on the display panel, and a low reflection layer disposed on the light control layer. The low reflection layer may include a first color material having a first molar extinction coefficient and a second color material having a second molar extinction coefficient. A functional group of the second color material maybe different from a functional group of the first color material. The first molar extinction coefficient may be smaller than the second molar extinction coefficient, and a content of the first color material may be smaller than a content of the second color material. The display device has improved color reproduction and reduced reflectance of external light due to the low reflection layer that includes color materials having different molar extinction coefficients.

### CROSS-REFERENCE TO RELATED APPLICATION(S)

This U.S. non-provisional patent application claims priority to and benefits of Korean Patent Application No. 10-2020-0074359 under 35 U.S.C. § 119, filed in the Korean Intellectual Property Office (KIPO) on Jun. 18, 2020, the entire contents of which are hereby incorporated by reference.

### BACKGROUND

### 1. Field of Disclosure

The disclosure relates to a display device and a method of manufacturing the same, and more specifically, to a display device having improved reliability and a method of manufacturing the display device.

### 2. Description of the Related Art

Various display devices for multimedia devices, such as television sets, mobile phones, tablet computers, game units, etc., are being developed. The display devices include various optical functional layers to provide a better color image to users.

Recently, the development of curved, rollable, and/or foldable display devices has led to research on display devices that are thinner but can still provide improved color reproduction range and visibility.

### SUMMARY

The disclosure provides a display device having improved color reproduction range and reduced external light reflectance.

The disclosure provides a method of manufacturing the display device having improved reliability.

Embodiments provide a display device that may include a display panel, a light control layer disposed on the display panel, and a low reflection layer disposed on the light control layer. The low reflection layer may include a first color material having a first molar extinction coefficient, and a second color material having a second molar extinction coefficient. A functional group of the second color material may be different from a functional group of the first color material. The first molar extinction coefficient may be smaller than the second molar extinction coefficient, and a content of the first color material may be smaller than a content of the second color material.

The first molar extinction coefficient may be equal to or greater than about 10³ M⁻¹ cm⁻¹ and smaller than about 10⁵ M⁻¹ cm⁻¹, and the second molar extinction coefficient may be equal to or greater than about 10⁵ M⁻¹ cm⁻¹.

A maximum absorption wavelength range of the first color material may be equal to or greater than about 500 nm and equal to or smaller than about 650 nm, and a maximum absorption wavelength range of the second color material may be equal to or greater than about 550 nm and equal to or smaller than about 630 nm.

The content of the first color material may be equal to or greater than about 2% and equal to or smaller than about 50% of the content of the second color material.

At least one of the first color material and the second color material may include compounds with a same functional group but different substituents.

The low reflection layer may include a base portion and protrusions protruding from the base portion and spaced apart from each other.

Each of the protrusions may have a width equal to or greater than about 10 nm and equal to or smaller than about 200 nm and a height equal to or greater than about 10 nm and equal to or smaller than about 200 nm.

A shortest distance between adjacent ones of the protrusions may be equal to or greater than about 10 nm and equal to or smaller than about 200 nm.

Each of the protrusions may have at least one of an upward convex shape with a curved surface, a hemi-spherical shape, a cylindrical shape, or a prismatic shape.

The display device may further include a light control auxiliary layer disposed between the light control layer and the low reflection layer.

The light control auxiliary layer may include a transflective layer and a phase control layer disposed on the transflective layer.

The transflective layer may include a metal layer.

The phase control layer may include at least one inorganic layer.

The display panel may be flexible.

Embodiments provide a display device that may include a display panel, a light control layer disposed on the display panel, and a low reflection layer disposed on the light control layer. The low reflection layer may include a first color material including one or more compounds, and a second color materials including one or more compounds. The first color material may include at least one of an anthraquinone-based compound, a phthalocyanine-based compound, and an azo-based compound, and the second color material may include at least one of a tetraazaporphyrin-based compound, a porphyrin-based compound, a squarylium-based compound, and a cyanine-based compound.

The first color material may have a molar extinction coefficient equal to or greater than about 10³ M⁻¹ cm⁻¹ and smaller than about 10⁵ M⁻¹ cm⁻¹, the second color material may have a molar extinction coefficient equal to or greater than about 10⁵ M⁻¹ cm⁻¹. The maximum absorption wavelength range of the first color material may be equal to or greater than about 500 nm and equal to or smaller than about 650 nm. The maximum absorption wavelength range of the second color material may be equal to or greater than about 550 nm and equal to or smaller than about 630 nm.

The low reflection layer may include a base portion and a plurality of protrusions disposed on the base portion and spaced apart from each other.

Embodiments provide a method of manufacturing a display device. The method may include providing a display panel, providing a light control layer on the display panel, and providing a low reflection layer on the light control layer. The providing of the low reflection layer may include providing a low reflection layer composition including a base resin, a first color material, and a second color material. The content of the second color material may be greater than a content of the first color material. A molar extinction coefficient of the second color material may be greater than a molar extinction coefficient of the first color material. A maximum absorption wavelength range of the second color material may be smaller than a maximum absorption wavelength range of the first color material.

The providing of the low reflection layer may include coating the low reflection layer composition on the light control layer, pressing the coated low reflection layer composition using a master mold, irradiating a light onto the master mold to form the low reflection layer, and separating the master mold.

A sum of the content of the first color material and the content of the second color material may be equal to or greater than about 0.2% or equal to or smaller than about 5% of the total content of the low reflection layer composition, and the content of the first color material may be equal to or greater than about 2% and equal to or smaller than about 50% of the content of the second color material.

According to the embodiments, the reflectance of the display device with respect to the external light is reduced, and the color reproduction range of the display device is improved.

### BRIEF DESCRIPTION OF THE DRAWINGS

The above and other advantages of the embodiments will become readily apparent by reference to the following detailed description when considered in conjunction with the accompanying drawings wherein:

FIG. 1 is a schematic perspective view showing a display device according to an embodiment;

FIG. 2 is an exploded schematic perspective view showing a display device according to an embodiment;

FIG. 3 is a schematic cross-sectional view showing a display device according to an embodiment;

FIG. 4A is a schematic cross-sectional view showing a low reflection layer according to an embodiment;

FIG. 4B is a schematic cross-sectional view showing a low reflection layer according to an embodiment;

FIG. 4C is a schematic cross-sectional view showing a low reflection layer according to an embodiment;

FIG. 5 is an enlarged schematic cross-sectional view showing the low reflection layer shown in FIG. 4A;

FIG. 6 is a schematic plan view showing a low reflection layer according to an embodiment;

FIG. 7 is a schematic perspective view showing a low reflection layer according to an embodiment;

FIG. 8 is a graph showing a reflectance as a function of a wavelength range according to an embodiment example and comparative examples;

FIG. 9 is a schematic cross-sectional view showing a display device according to an embodiment;

FIG. 10 is a schematic cross-sectional view showing a light control auxiliary layer according to an embodiment;

FIG. 11 is a flowchart showing a method of manufacturing a display device according to an embodiment;

FIG. 12 is a flowchart showing a process of a method of providing a low reflection layer according to an embodiment;

FIG. 13A is a schematic cross-sectional view showing a process of the method of manufacturing the display device according to an embodiment;

FIG. 13B is a schematic cross-sectional view showing a process of the method of manufacturing the display device according to an embodiment;

FIG. 13C is a schematic cross-sectional view showing a process of the method of manufacturing the display device according to an embodiment; and

FIG. 13D is a schematic cross-sectional view showing a process of the method of manufacturing the display device according to an embodiment.

### DETAILED DESCRIPTION OF THE EMBODIMENTS

The disclosure and the embodiments thereof may be variously modified and realized in many different forms. Although some embodiments are disclosed in the drawings and described in the disclosure, the embodiments should not be limited to the specific disclosed forms. Instead, the disclosure and the embodiments thereof should be construed to include all modifications, equivalents, or replacements included in the spirit and scope of the disclosure.

The drawings and description are to be regarded as only illustrative in nature, and thus are not limiting of embodiments described and claimed herein. Some of the parts which are not associated with the description may not be provided in order to describe embodiments of the invention and like reference numerals refer to like elements throughout the specification.

In the drawings, a size and thickness of each element are arbitrarily represented for better understanding and ease of description, however the invention is not limited thereto. In the drawings, the thickness of layers, films, panels, regions, and other elements may be exaggerated for clarity. In the drawings, for better understanding and ease of description, the thicknesses of some layers and areas may be exaggerated.

Further, in the specification, the phrase “in a plan view” means when an object portion is viewed from above, and the phrase “in a cross-sectional view” means when a cross-section taken by vertically cutting an object portion is viewed from the side. Additionally, the terms “overlap” or “overlapped” means that a first object may be above or below a second object, and vice versa.

Throughout the specification, when an element is referred to as being “connected” to another element, the element may be “directly connected” to another element, or “electrically connected” to another element with one or more intervening elements interposed therebetween.

When a layer, film, region, substrate, or area, is referred to as being “on” another layer, film, region, substrate, or area, it may be directly on the other film, region, substrate, or area, or intervening films, regions, substrates, or areas, may be present therebetween. Conversely, when a layer, film, region, substrate, or area, is referred to as being “directly on” another layer, film, region, substrate, or area, intervening layers, films, regions, substrates, or areas, may be absent therebetween. Further when a layer, film, region, substrate, or area, is referred to as being “below” another layer, film, region, substrate, or area, it may be directly below the other layer, film, region, substrate, or area, or intervening layers, films, regions, substrates, or areas, may be present therebetween. Conversely, when a layer, film, region, substrate, or area, is referred to as being “directly below” another layer, film, region, substrate, or area, intervening layers, films, regions, substrates, or areas, may be absent therebetween. Further, “over” or “on” may include positioning on or below an object and does not necessarily imply a direction based upon gravity.

Like numerals refer to like elements throughout. In the drawings, the thickness, ratio, and dimension of components are exaggerated for effective description of the technical content.

As used herein, the term “and/or” includes any and all combinations of one or more of the associated listed items. In the specification and the claims, the phrase “at least one of” is intended to include the meaning of “at least one selected from the group of” for the purpose of its meaning and interpretation. For example, “at least one of A and B” may be understood to mean “A, B, or A and B.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 80%, 5% of the stated value.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another region, layer or section. For example, when “a first element” is discussed in the description, it may be termed “a second element” or “a third element,” and “a second element” and “a third element” may be termed in a similar manner without departing from the teachings herein. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as shown in the figures. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, a display device and a method of manufacturing the display device according to the disclosure will be explained in detail with reference to the accompanying drawings.

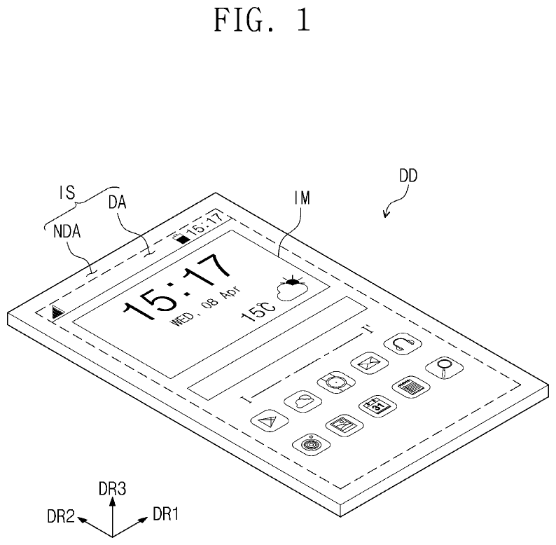

FIG. 1 is a schematic perspective view showing a display device DD according to an embodiment. FIG. 1 shows a mobile electronic device as an example of the display device DD. The display device DD may also be applied to large devices such as television sets, monitors, outdoor billboards, as well as small and medium-sized devices, such as personal computers, notebook computers, personal digital assistants, car navigation units, game units, smartphones, tablet computers, cameras, and the like. The display device DD may be applied to other electronic devices as long as they do not depart from the concept of the disclosure.

The display device DD may have a hexahedron (box) shape with a thickness in a third directional axis DR3 on a plane defined by a first directional axis DR1 and a second directional axis DR2 crossing the first directional axis DR1. However, the embodiments are not limited thereto, and the display device DD may have a variety of shapes.

In an embodiment, upper (or front) and lower (or rear) surfaces of each member are defined with respect to a direction in which an image IM is displayed. The front and rear surfaces are opposite to each other in the third directional axis DR3, and the front and lower surfaces may have a normal direction that is substantially parallel to the third directional axis DR3.

The directions indicated by the first, second, and third directional axes DR1, DR2, and DR3 may be defined relative to each other and may be geometrically transformed to align with other directions. Hereinafter, the first, second, and third directions and the first, second, and third directional axes DR1, DR2, and DR3 are assigned with the same reference numerals.

The display device DD may display the image IM through a display surface IS. The display surface IS may include a display area DA and a non-display area NDA adjacent to the display area DA. The image IM is not displayed through the non-display area NDA. The image IM may include a still image or a video image. FIG. 1 shows multiple application icons and a clock widget as representative examples of the image IM.

The display area DA may have a quadrangular (rectangular) shape. The non-display area NDA may surround the display area DA. However, the embodiments are not limited to specific shapes of the display area DA and the non-display area NDA. For example, the non-display area NDA may even be eliminated entirely from the front surface of the display device DD.

The display device DD may be flexible. The display device DD may be fully bendable or may be bendable in the scale of nanometers (e.g., a few or several nanometers). For example, the display device DD may be a curved display device or a foldable display device. However, the embodiments are not limited to the flexible or bendable display devices and may also include rigid display devices.

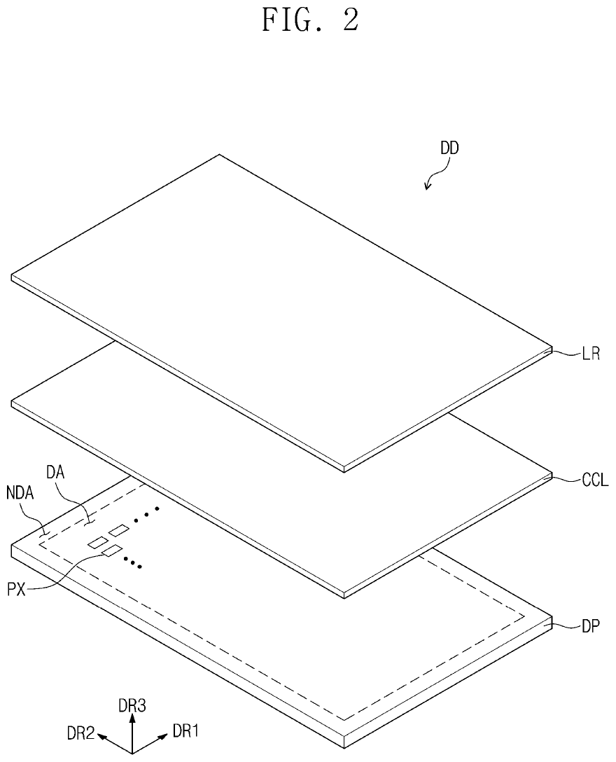

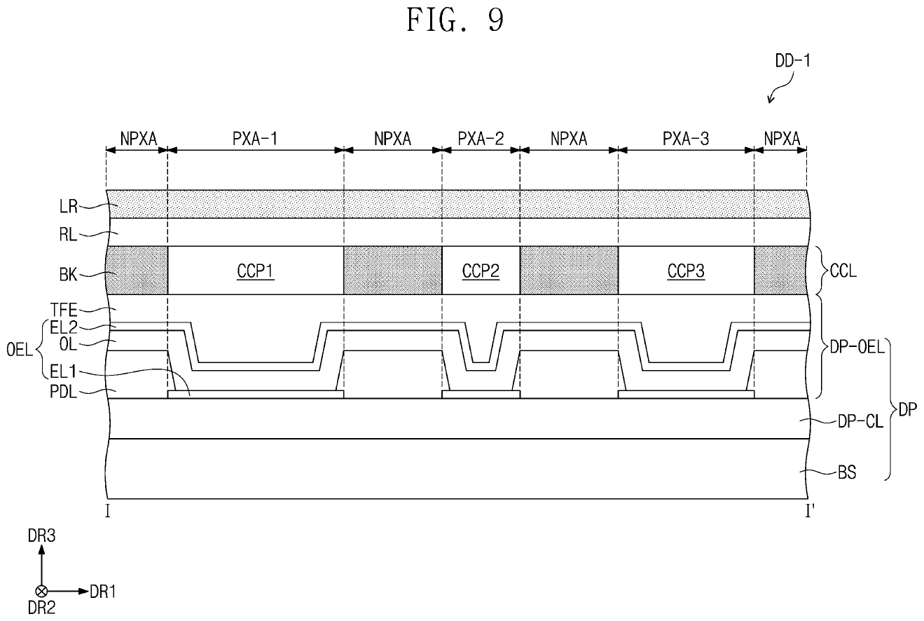

FIG. 2 is an exploded perspective view showing the display device DD according to an embodiment. Referring to FIG. 2, the display device DD may include a display panel DP, a light control layer CCL, and a low reflection layer LR. Although not shown in FIG. 2, a light control auxiliary layer RL (refer to FIG. 9) may be further disposed between the light control layer CCL and the low reflection layer LR.

The display panel DP may include multiple pixels PX arranged in areas corresponding to the display area DA of the display device DD. The pixels PX may generate lights in response to electrical signals. The display area DA may display the image IM corresponding to the lights generated by the pixels PX. The pixels PX may be arranged in the display area DA to be spaced apart from each other.

The display panel DP according to an embodiment may be a light emission display panel. For instance, the display panel DP may include a liquid crystal display panel, an organic light emitting display panel, or a quantum dot light emitting display panel. However, the embodiments are not limited by the type of display panel DP. Hereinafter, an organic light emitting display panel will be described as an example of display panel DP.

The light control layer CCL may include light control portions disposed on the display panel DP and converting light emitted from the display panel DP into lights having different wavelengths from each other. The lights output from the light control layer CCL may have different colors.

The low reflection layer LR may be disposed on the light control layer CCL and may reduce a reflectance of external incident light on the display panel DP, and thus, the visibility of the lights generated by the display panel DP may be improved. In addition, the low reflection layer LR may improve a color reproduction range of the light generated by the display panel DP. The low reflection layer LR may cover the front surface of the display panel DP and the light control layer CCL and may protect the display panel DP and the light control layer CCL.

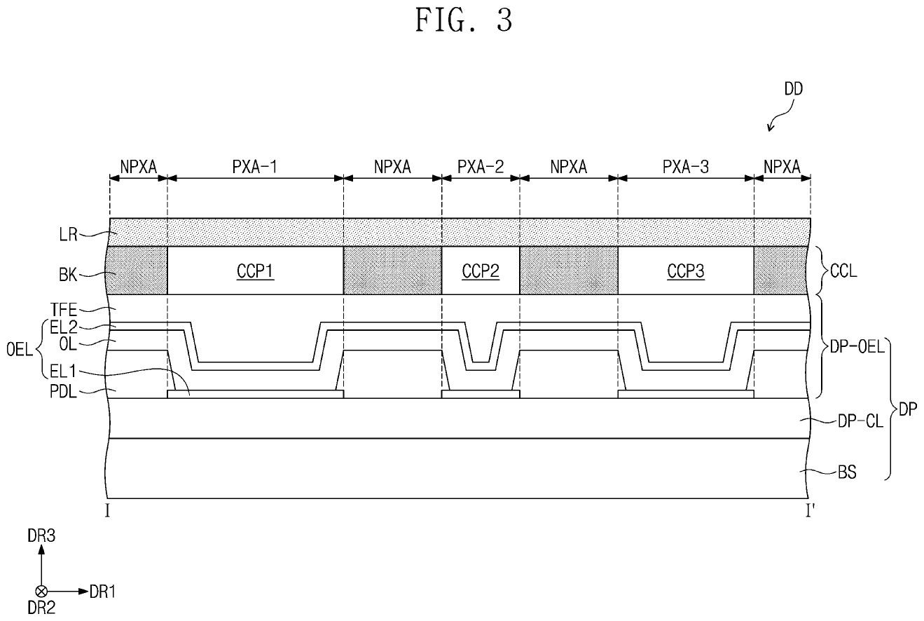

FIG. 3 is a schematic cross-sectional view taken along a line I-I′ of FIG. 1.

Referring to FIG. 3, the display device DD includes the display panel DP, the light control layer CCL, and the low reflection layer LR, which are sequentially stacked on each other. The display panel DP may include a base layer BS, a circuit layer DP-CL, and a light emitting element layer DP-OEL, which are sequentially stacked on each other.

In an embodiment, the low reflection layer LR may include a first color material having a first molar extinction coefficient and a second color material having a second molar extinction coefficient different from that of the first color material. A functional group of the second color material may be different from a functional group of the first color material. By including two or more types of color materials having different molar extinction coefficients and each having a functional group different from each other, the visibility and the color reproduction range of the lights generated by the display panel DP may be improved. The low reflection layer LR will be described in further detail below.

In an embodiment, the base layer BS included in the display panel DP may be rigid or flexible. The base layer BS may be a polymer substrate, a plastic substrate, a glass substrate, a metal substrate, or a composite material substrate. For example, the base layer BS may be a substrate that is flexible and includes a polyimide-based resin. However, the embodiments are not limited by the material included in the base layer BS.

The circuit layer DP-CL may be disposed on the base layer BS. Although not shown in FIG. 3, the circuit layer DP-CL may include transistors. Each of the transistors may include a control electrode, an input electrode, and an output electrode. For example, the circuit layer DP-CL may include a switching transistor and a driving transistor to drive a light emitting element OEL.

The light emitting element layer DP-OEL may be disposed on the circuit layer DP-CL. The light emitting element layer DP-OEL may include a pixel definition layer PDL, the light emitting element OEL, and an encapsulation layer TFE.

The light emitting element OEL may include a first electrode EL1, a second electrode EL2 facing the first electrode EL1, and a light emitting layer OL disposed between the first electrode EL1 and the second electrode EL2. Although not shown in FIG. 3, the light emitting element OEL may further include a hole transport region and an electron transport region. The hole transport region may be a region of a layer that transport holes injected from the first electrode EL1 to the light emitting layer OL. The electron transport region may be a region of a layer that transports electrons injected from the second electrode EL2 to the light emitting layer OL. The light emitting element OEL may include the hole transport region, light emitting layer OL, and the electron transport region sequentially stacked on each other.

The light emitting element OEL may recombine holes injected from the first electrode EL1 with electrons injected from the second electrode EL2 to generate a light. For example, the light emitting layer OL may generate blue light. The light emitting element layer DP-OEL may output the light from the light emitting layer OL through the front surface of the display device DD.

The pixel definition layer PDL may be disposed on the circuit layer DP-CL. The pixel definition layer PDL may be provided with openings defined therethrough. The openings defined through the pixel definition layer PDL may correspond to light emitting areas PXA-1, PXA-2, and PXA-3, respectively. The pixel definition layer PDL may correspond to the non-light-emitting area NPXA.

The pixel definition layer PDL may include an organic resin or an inorganic material. For example, the pixel definition layer PDL may include a polyacrylate-based resin, a polyimide-based resin, silicon nitride (SiNx), silicon oxide (SiOx), or silicon oxynitride (SiOxNy).

The light emitting areas PXA-1, PXA-2, and PXA-3 may have different sizes from each other. For example, the light emitting areas PXA-1, PXA-2, and PXA-3 may have different sizes from each other depending on the color of the lights emitted therethrough. As each light emitting area has a suitable size for the color of the light emitted therethrough, light efficiency may be uniform across a variety of colors. However, the embodiments are not limited thereto, and the light emitting areas PXA-1, PXA-2, and PXA-3 may have the same size as each other.

The encapsulation layer TFE may be disposed on the light emitting element OEL to encapsulate the light emitting element OEL. The encapsulation layer TFE may protect the light emitting element OEL from moisture and oxygen and may protect the light emitting element OEL from foreign substances, such as dust particles.

FIG. 3 shows the encapsulation layer TFE as a single layer, however, the encapsulation layer TFE may include at least one organic layer or inorganic layer or may include organic and inorganic layers. For example, the encapsulation layer TFE may also have a structure in which the organic layer and the inorganic layer are alternately stacked on each other, or a structure in which an inorganic layer, an organic layer, and another inorganic layer are sequentially stacked on each other.

The inorganic layer included in the encapsulation layer TFE may include a silicon nitride layer, a silicon oxynitride layer, a silicon oxide layer, a titanium oxide layer, or an aluminum oxide layer, however, it should not be limited thereto. The organic layer may include an acrylic-based organic layer, but it should not be limited thereto.

The light control layer CCL may be disposed on the encapsulation layer TFE included in the display panel DP. An overcoat layer may be further disposed between the encapsulation layer TFE and the light control layer CCL. The overcoat layer may be a planarization layer or a buffer layer.

The light control layer CCL may include first, second, and third light control portions CCP1, CCP2, and CCP3, and a barrier wall BK. The light control portions CCP1, CCP2, and CCP3 may be spaced apart from each other by the barrier wall BK.

At least one of the first, second, and third light control portions CCP1, CCP2, and CCP3 may include quantum dots. The quantum dots may convert the wavelength of the light generated by the light emitting element OEL.

The first light control portion CCP1 may include red quantum dots and may convert the blue light to a red light. The second light control portion CCP2 may include green quantum dots and may convert the blue light to a green light. The third light control portion CCP3 may transmit the blue light. The third light control portion CCP3 may be formed of a transparent resin or may further include a blue pigment or a blue dye.

The light control portions CCP1, CCP2, and CCP3 may further include scatterers to increase a light emission efficiency of the display device DD. The scatterers may be a material that scatters the light in various directions, and may include at least one of TiO₂, ZrO₃, Al₂O₃, SiO₂, MgO, In₂O₃, ZnO, SnO₂, Sb₂O₃, and SiO₂.

The barrier wall BK may correspond to the boundaries between the light control portions CCP1, CCP2, and CCP3. The barrier wall BK may overlap the non-light-emitting area NPXA in a plan view. The barrier wall BK may prevent light leakage from occurring. The barrier wall BK may include an organic light blocking material, a black pigment, or a black dye.

In an embodiment, the low reflection layer LR may be disposed on the light control layer CCL. The low reflection layer LR disposed on the light control layer CCL may improve the color reproduction range of the lights exiting from the light control portions CCP1, CPP2, and CCP3 and having different wavelength ranges and different colors from each other. In addition, the low reflection layer LR may reduce the reflectance with respect to the external incident light incident, and thereby improve the visibility of display device DD against the external light. The low reflection layer LR may also cover and protect the light control layer CCL and other components disposed under the low reflection layer LR.

The low reflection layer LR may include a first color material and a second color material which have a different functional group. For example, the first color material may include at least one of an anthraquinone-based compound, a phthalocyanine-based compound, an azo-based compound, a perylene-based compound, a xanthene-based compound, a diimmonium-based compound, and a dipyrromethene-based compound. The second color material may include at least one of a tetraazaporphyrin-based compound, a porphyrin-based compound, a squarylium-based compound, an oxazine-based compound, a triarylmethane-based compound, and a cyanine-based compound.

In another example, the first color material may include at least one of the anthraquinone-based compound, the phthalocyanine-based compound, and the azo-based compound, and the second color material may include at least one of the tetraazaporphyrin-based compound, the porphyrin-based compound, the squarylium-based compound, and the cyanine-based compound. However, the embodiments should not be limited to these specific compounds for the first and second color materials.

The functional group of the compound may influence its molar extinction coefficient and its extinction wavelength range. The first and second color materials, having different functional groups from each other, may have different molar extinction coefficients and different maximum absorption wavelength ranges.

The functional group refers to a specific atomic group or structure that plays an important role in determining the properties of the compound. One of the functional groups of the color material may include a chromophore group that is responsible for the color of the compound may be included. For example, the functional group may include anthraquinone, phthalocyanine, azo, perylene, xanthene, diimmonium, dipyrromethene, tetraazaporphyrin, porphyrin, squarylium, oxazine, triarylmethane, cyanine, and others. A color material having a specific functional group structure may be named as a specific material-based compound. For example, a compound having an anthraquinone structure may be referred to as an anthraquinone-based compound.

In an embodiment, the first and second color materials may have different molar extinction coefficients from each other. The first color material may have a first molar extinction coefficient, the second color material may have a second molar extinction coefficient, and the first molar extinction coefficient may be smaller than the second molar extinction coefficient. The first molar extinction coefficient may be equal to or greater than about 10³ M⁻¹ cm⁻¹ and smaller than about 10⁵ M⁻¹ cm⁻¹, and the second molar extinction coefficient may be equal to or greater than about 10⁵ M⁻¹ cm⁻¹.

The maximum absorption wavelength range of the second color material may be smaller than the maximum absorption wavelength range of the first color material. The second color material having the molar extinction coefficient greater than that of the first color material may have the maximum absorption wavelength range corresponding to a portion (or subset) of the maximum absorption wavelength range of the first color material. For example, the maximum absorption wavelength range of the first color material may be equal to or greater than about 500 nm and equal to or smaller than about 650 nm, and the maximum absorption wavelength range of the second color material may be equal to or greater than about 550 nm and equal to or smaller than about 630 nm.

Since the first color material absorbs a wider range of light than the second color material, the first color material may reduce reflectance in a wider wavelength range than the second color material. Because the second color material has a greater molar extinction coefficient than the first color material, the second color material may have a greater reduction of reflectance in a specific wavelength range that is smaller than that of the first color material. In addition, the second color material may reduce the transmittance of a specific wavelength range, and thus, may improve the color reproduction range. For example, the second color material may reduce the transmittance of light corresponding to a wavelength range between peak wavelengths of the green and red lights exiting from the display device and output light with more vivid color.

In the embodiments, the first and second color materials may include one or more compounds that satisfy the previous molar extinction coefficients and maximum absorption wavelength ranges. The first color material may include a compound different from a compound included in the second color material. The first color material may include compounds with a same functional group but different substituents and the second color materials may include compounds with a same functional group but different substituents. The functional group of the compounds of the first color material may be different from the functional group of the compounds of the second color material. The first color materials may include two or more compounds that have different functional groups from each other and have the first molar extinction coefficient of about 10³ M⁻¹ cm⁻¹ or more and about 10⁵ M⁻¹ cm⁻¹ or less. The second color materials may also include two or more compounds that have different functional groups from each other and have the second molar extinction coefficient of about 10⁵ M⁻¹ cm⁻¹ or more.

In an embodiment, the first color material may include anthraquinone-based compounds with different substituents. In another embodiment, the compounds included in the first color material may include anthraquinone-based compounds and phthalocyanine-based compounds.

In an embodiment, in the low reflection layer, the content of the first color material may be smaller than the content of the second color material. The content of the second color material, having the molar extinction coefficient greater than that of the first color material, may be greater than the content of the first color material. For example, the content of the first color material may be equal to or greater than about 2% and equal to or smaller than about 50% of the content of the second color material. The ratio of the content of the first color material to the second color material in the low reflection layer may be about 0.02:1 to about 0.5:1. When the content of the first color material is smaller than about 2%, the light absorption rate of the relatively wide wavelength range is lowered, and reflectance of external light may be reduced by less. When the content of the first color material is greater than about 50%, the amount of the light absorbed by the second color material is reduced, and improvement in the color reproduction range by the second color material is reduced.

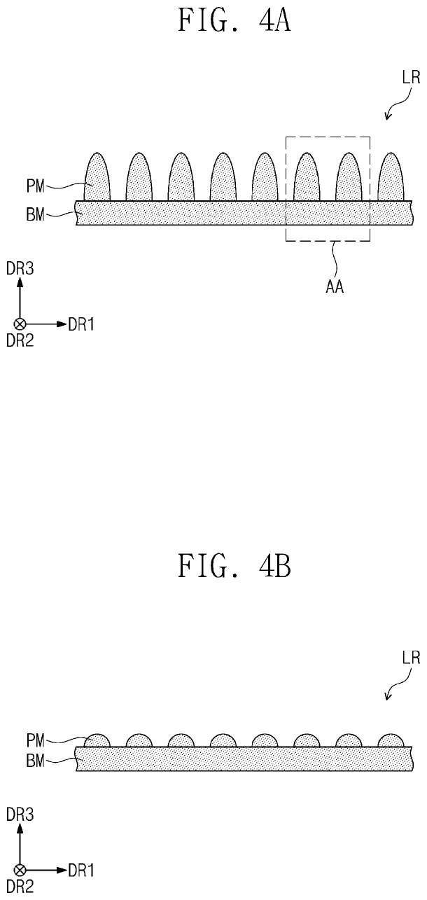

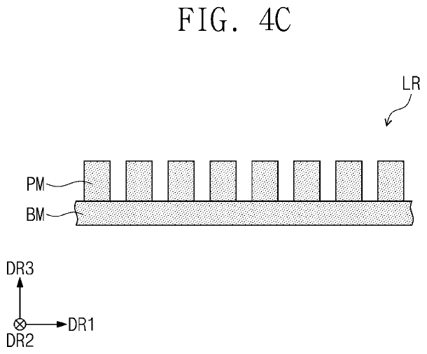

In embodiments, the low reflection layer LR may have an integral shape (or a unitary structure) and may cover the light control layer CCL. For example, the low reflection layer LR may have an integral plate shape (or a single layer shape). In other embodiments, the low reflection layer LR may include a base portion BM (refer to FIG. 4A) and multiple protrusions PM (refer to FIG. 4A) protruding from the base portion BM (refer to FIG. 4A) and spaced apart from each other. The protrusions PM (refer to FIG. 4A) may have a variety of three-dimensional shapes. The protrusions PM (refer to FIG. 4A) may have a convex shape with a curved surface. For example, the cross-sections of the protrusions PM may have a parabolic shape, a semi-circular shape, or a semi-oval shape in cross-section. The protrusions PM may also have a cylindrical shape or a prismatic shape.

FIGS. 4A to 4C show schematic cross-sectional views of low reflection layers LR according to embodiments. The low reflection layers LR may include the base portion BM and the protrusions PM, and the protrusions PM may have a variety of shapes.

FIG. 4A shows an embodiment where the protrusion PM may include a curved surface on a front (upper) surface and may have a convex shape upward. The protrusion PM may have a parabolic shape in a cross-section view. The inclination (slope) of the tangent lines of the parabolic shape may gradually decrease from the points where the base portion BM is in contact with the protrusion PM to the highest point of the protrusion PM. FIG. 4B shows an embodiment where the protrusion PM may have a hemispherical shape. The protrusion PM may have the semi-circular shape in a cross-section view. In the embodiment shown in FIG. 4C, the protrusion PM may have a cylindrical shape or prismatic shape. The protrusion PM may have a quadrangular (rectangular) shape in a cross-section view.

The embodiments are not limited to the examples shown in FIGS. 4A to 4C and the protrusions PM may have other shapes.

In the embodiments, the base portion BM and the protrusions PM may be integrally formed with each other from the same material. For example, the base portion BM and the protrusions PM may include the same base resin and the same first and second color materials.

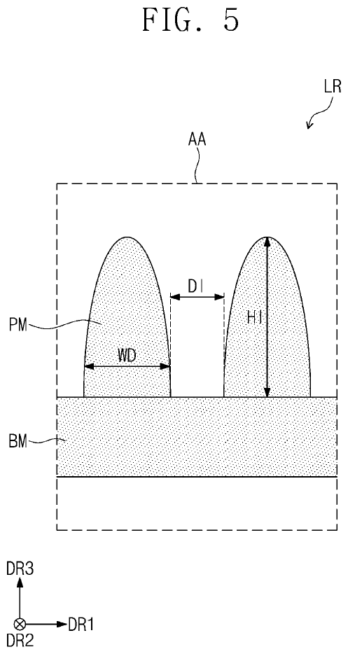

FIG. 5 shows an enlarged schematic cross-sectional view of an area AA of the low reflection layer LR in FIG. 4A. FIG. 5 shows the width WD and the height HI of the protrusions PM. The protrusions PM may have shapes in which the width WD may decrease in the third directional axis DR3. In FIG. 5, the protrusions PM may have a parabolic shape in a cross-section view. The width WD of a protrusion PM may be defined as its greatest width in the first directional axis DR1. In other embodiments, when the protrusion PM has a hemispherical shape, the width WD may be a diameter of a spherical shape. The height HI may be the distance between the surface where the base portion BM is in contact with the protrusion PM and the highest point of the protrusion PM in the third directional axis DR3.

In the embodiments, the protrusions PM may have a size ranging from about ten nanometers to about several hundreds of nanometers. For example, the width WD of the protrusions PM may be equal to or greater than about 10 nm and equal to or smaller than about 200 nm, and the height HI of the protrusions PM may be equal to or greater than about 10 nm and equal to or smaller than about 200 nm.

Distances between the protrusions adjacent to each other may range from about ten nanometers to about several hundreds of nanometers. For example, referring to FIG. 5, a minimum distance DI between the protrusions adjacent to each other among the protrusions PM may be equal to or greater than about 10 nm and equal to or smaller than about 200 nm.

When the protrusions PM having a nano-scale size are arranged at an interval shorter than a wavelength of the light, the light may behave as if the low reflection layer LR is a single medium. The generation of diffraction waves may be prevented by the protrusions PM, and the effective refractive index may be gradually changed or transitioned. As a result, the protrusions PM may reduce the reflectance of the external light.

When the height HI of the protrusions PM exceeds about 200 nm, there is less decrease in the reflectance of the external light by the protrusions PM, and the low reflection layer LR may become thicker. When the low reflection layer LR disposed on the front surface of the display panel DP receives impacts applied to the display device DD, the protrusions PM may be damaged.

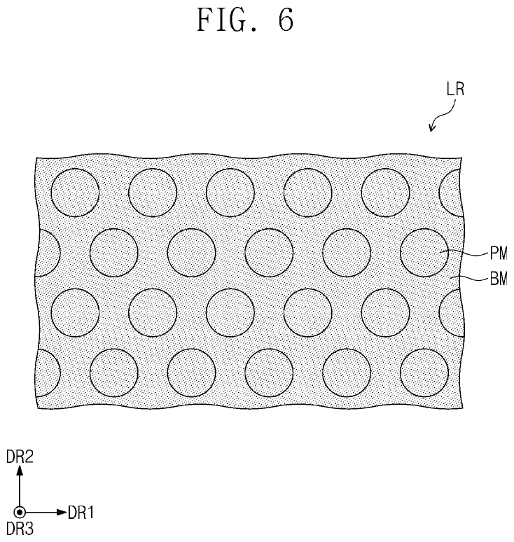

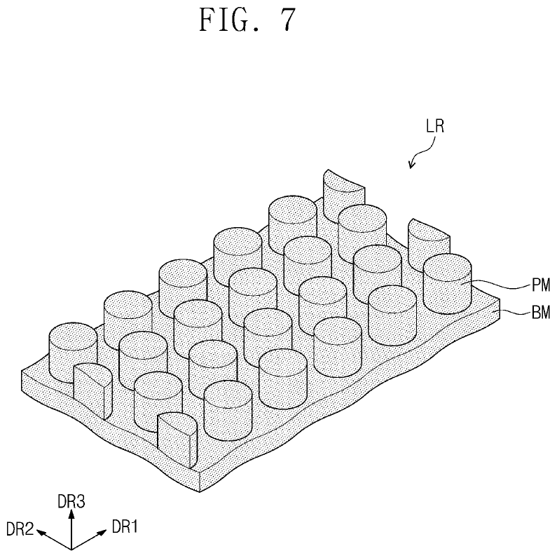

FIG. 6 is a plan view showing a low reflection layer LR according to an embodiment, and FIG. 7 shows a perspective view of the low reflection layer LR according to an embodiment. FIGS. 6 and 7 show the protrusions PM having a cylindrical shape (among the various possible shapes) according to an embodiment. Referring to FIGS. 6 and 7, the protrusions PM included in the low reflection layer LR may be arranged in patterns on the base portion BM at regular intervals or according to specific rules.

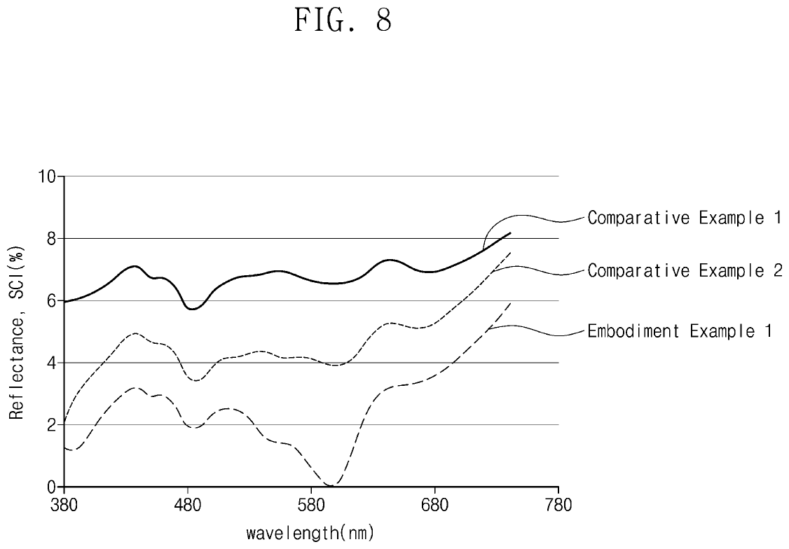

FIG. 8 is a graph showing a reflectance as a function of a wavelength range of a display device according to an embodiment example and comparative examples 1 and 2. The horizontal axis of the graph shows the wavelength of an external light, and the vertical axis shows the reflectance of light as a percentage measured by the Specular Component Included (SCI) method. Embodiment example 1, comparative example 1, and comparative example 2, have identical configurations, as shown in FIG. 3, except for the low reflection layer.

Embodiment example 1 includes a low reflection layer with the first and second color materials and nano-pattern shapes. Comparative example 1 includes a low reflection layer with only the first color material and formed in a single layer without nano-pattern shapes. Comparative example 2 includes a low reflection layer with only the first color material and the nano-pattern shape. The first color material is an anthraquinone-based compound, the second color material is a tetraazaporphyrin-based compound. In embodiment example 1, the content of the first color material is about 50% of the content of the second color material.

According to FIG. 8, the light reflectance of embodiment example 1 is reduced when compared with the light reflectance of comparative example 1 and comparative example 2 across the entire wavelength range corresponding to a visible light region. The light reflectance of embodiment example 1 was further reduced in the wavelength range from about 500 nm to about 650 nm, with even greater reduction in the range from about 550 nm to about 630 nm. The light reflectance is close to about 0% in the wavelength range of about 600 nm.

Comparative example 1 and comparative example 2 include only the first color material while embodiment example 1 includes the first and second color materials having different functional groups from each other and different molar extinction coefficients from each other. When embodiment example 1 is compared with comparative example 2, both of which include the nano-pattern shapes, embodiment example 1 was more significantly reduced than that in comparative example 2. Therefore, the light reflectance decreases in the entire visible wavelength range when the low reflection layer including the first and second color materials having different molar extinction coefficients and different functional groups.

In embodiment example 1, the light reflectance was significantly reduced in the wavelength range from about 500 nm to about 650 nm, which includes the maximum absorption wavelength range of the first color material and the second color material. The light reflectance of embodiment example 1 was further reduced in the wavelength range from about 550 nm to about 630 nm by the second color material whose content and molar extinction coefficient are greater than those of the first color material. The second color material may also improve the color reproduction range by significantly reducing reflectance in a wavelength range corresponding to the peak wavelength region of the green light and the peak wavelength region of the red light.

The shape of the low reflection layer may influence light reflectance. Comparative example 1 includes a low reflection layer formed in a single layer, while comparative example 2 and embodiment example 1 include nano-pattern shapes. When a value of the light reflectance of each embodiment example 1 and comparative example 2 is compared with a value of the light reflectance of comparative example 1, the light reflectance of each embodiment example 1 and comparative example 2 is reduced (lower) in the entire wavelength range corresponding to the visible light region (across the entire visible light wavelength range). The protrusions included in the low reflection layer are arranged in intervals shorter than the wavelength of the light, and thus, reduce the reflectance of the external light.

Through the light reflectance of embodiment example 1, it was observed that the low reflection layer including the first and second color materials having different molar extinction coefficients, different maximum absorption wavelength ranges, different contents, and different functional groups reduces the reflectance of the external light of the display device and improves the color reproduction range. In addition, the low reflection layer having the nano-pattern shapes further reduce reflectance of the external light.

As the color reproduction range increases, a wider variety of colors and colors that are close to nature (i.e., natural-looking colors) may be displayed. The color reproduction range of a display device DD according to the embodiments, which includes the low reflection layer LR having the first and second color materials, may increase by about 9% (or to about 109.3%) compared to the color reproduction range of a display device which does not include the low reflection layer. Display devices with improved reliability may be provided to the user by the low reflection layer including the first color material and the second color material.

The color material included in the low reflection layer LR may reduce the transmittance of the light in a wavelength range from about 500 nm to about 650 nm, and may further reduce transmittance in the wavelength range from about 550 nm to about 630 nm. The transmittance of the light corresponding to a peripheral wavelength region between the peak wavelengths of the green and red light output from the display device DD may be significantly reduced. Green light and red light close to pure colors may be output from the display device DD by the color materials included in the low reflection layer LR, and the color reproduction range of the display device DD may increase.

FIG. 9 is a schematic cross-sectional view showing a display device DD-1 according to an embodiment. The display device DD-1 may further include a light control auxiliary layer RL disposed between a light control layer CCL and a low reflection layer LR. The light control auxiliary layer RL may increase the light emission efficiency of light output from display panel DP.

FIG. 10 is a schematic cross-sectional view showing the light control auxiliary layer RL according to an embodiment. The light control auxiliary layer RL may include a transflective layer MTL and a phase control layer PA, which are sequentially stacked on each other.

The transflective layer MTL may have a transflective property of both transmitting and reflecting light. When the light emitted from the display panel DP is not converted into a light having a different wavelength range within the light control portions CCP1, CCP2, and CCP3, the transflective layer MTL may reflect the light back into the light control portions CCP1, CCP2, and CCP3. The transflective layer MTL may reduce a possibility that the light, which is not converted in the light control portions CCP1, CCP2, and CCP3, is emitted as it is or is extinguished, and thus may increase the light emission efficiency of the light emitted from the display device DD-1.

The transflective layer MTL may be a metal layer. The transflective layer MTL may include Cr, Mo, Co, Pt, Ag, Al, Au, Ti, Cu, Fe, Ni, or alloys thereof.

The phase control layer PA may be disposed on the transflective layer MTL. The phase control layer PA may include at least one inorganic layer. As shown in FIG. 10, the phase control layer PA may include a plurality of inorganic layers IO1 and IO2 sequentially stacked on each other.

The phase control layer PA uses light absorption and optical extinction (destructive) interference and, together with the transflective layer MTL, ensures that the light output from the display panel is converted into a light in a desired wavelength range while passing through the light control portions. The phase control layer PA may absorb and/or cancel external light to reduce the reflectance of the external light.

The inorganic layers IO1 and IO2 included in the phase control layer PA may include different types of inorganic materials. For example, a first inorganic layer IO1 disposed on the transflective layer MTL may include MTO, and a second inorganic layer IO2 may include ITO. However, the embodiments are not limited to these specific materials for the inorganic layers IO2 and IO2.

Depending on the material and thickness of the transflective layer MTL and the phase control layer PA, the degree of improvement in light emission efficiency may vary. The transflective layer MTL may include Ag and may have a thickness of about 5 nm to about 15 nm, the first inorganic layer IO1 may include MTO and may have a thickness of about 30 nm to about 40 nm, and the second inorganic layer IO2 may include ITO, may have a thickness equal to or smaller than about 30 nm, or may be omitted. However, the embodiments are not limited thereto.

Referring to FIGS. 3 and 10, at least one of the light control portions CCP1, CCP2, and CCP3 may include quantum dots. The quantum dots may be semiconductor nanocrystals that are selected from a group II-VI compound, a group III-VI compound, a group III-V compound, a group IV-VI compound, a group IV element, a group IV compound, a group I-III-VI compound, or a combination thereof.

The group II-VI compound may be selected from a binary compound selected from the group consisting of CdS, CdSe, CdTe, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound of In₂S₃ or In₂Se₃, a ternary compound of InGaS₃ or InGaSe₃, or a combination thereof.

The group III-V compound may be selected from a binary compound selected from the group consisting of GaN, GaP, GaAs, GaSb, MN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, and a mixture thereof, and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group III-V compound may further include a group II metal such as InZnP.

The group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

The group compound may include a ternary compound of AgInS, AgInS₂, CuInS, CuInS₂, CuGaO₂, AgGaO₂, AgAlO₂, or an arbitrary combination thereof.

The binary, ternary, or quaternary compounds may exist in particles at uniform concentrations, or they may exist in the same particle after being divided into portions having different concentrations.

Each quantum dot may have a core-shell structure that includes a core and a shell surrounding the core. Quantum dots may have a core-shell structure where one quantum dot surrounds another quantum dot. In the core-shell structure, the concentration of elements existing in the shell may have a concentration gradient that may decrease toward the core.

The shell of the quantum dots may include metals or non-metal oxides, semiconductor compounds, or combinations thereof.

The metals or non-metal oxides used for the shell include binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, or, NiO, ternary compounds, such as MgAl₂O₄, CoFe₂O₄, NiFe₂O₄, or CoMn₂O₄. However, the embodiments are not limited thereto.

The semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb. However, the embodiments are not limited thereto.

The quantum dots may control the color of the emitted light depending on their particle size. The quantum dots may have various emission colors such as green and red. As the particle size of the quantum dot decreases, the wavelength of the light emitted from the quantum dot becomes shorter. The particle size of the quantum dots emitting the green light may be smaller than the particle size of the quantum dots emitting the red light.

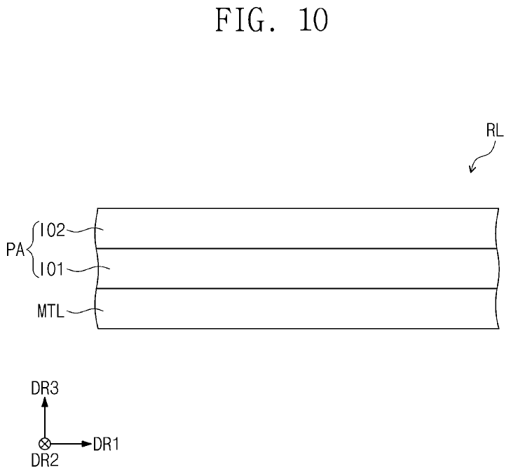

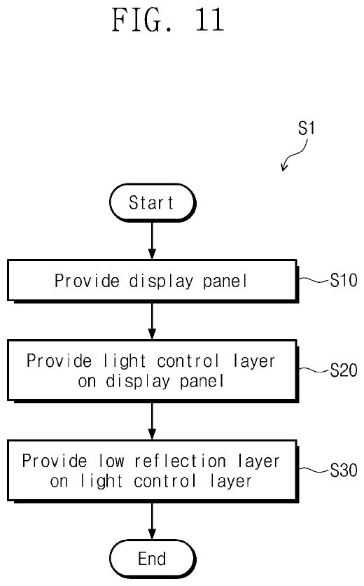

FIG. 11 is a flowchart showing a method of manufacturing a display device according to an embodiment. The manufacturing method includes providing a display panel (S10), providing a light control layer on the display panel (S20), and providing a low reflection layer on the light control layer (S30).

The manufacturing method according to an embodiment may further include providing a light control auxiliary layer after providing the light control layer (S20). The low reflection layer may be disposed on the light control auxiliary layer.

The display panel, the light control layer, and the light control auxiliary layer, which are provided by the manufacturing method of the display device according to the embodiments, may be substantially the same as the display panel DP, the light control layer CCL, and the light control auxiliary layer RL described in FIGS. 3, 9, and 10.

Providing the low reflection layer may include providing a low reflection layer composition that includes the base resin, the first color material, and the second color material. The first color material and the second color material may be substantially the same as the first and second color materials previously described.

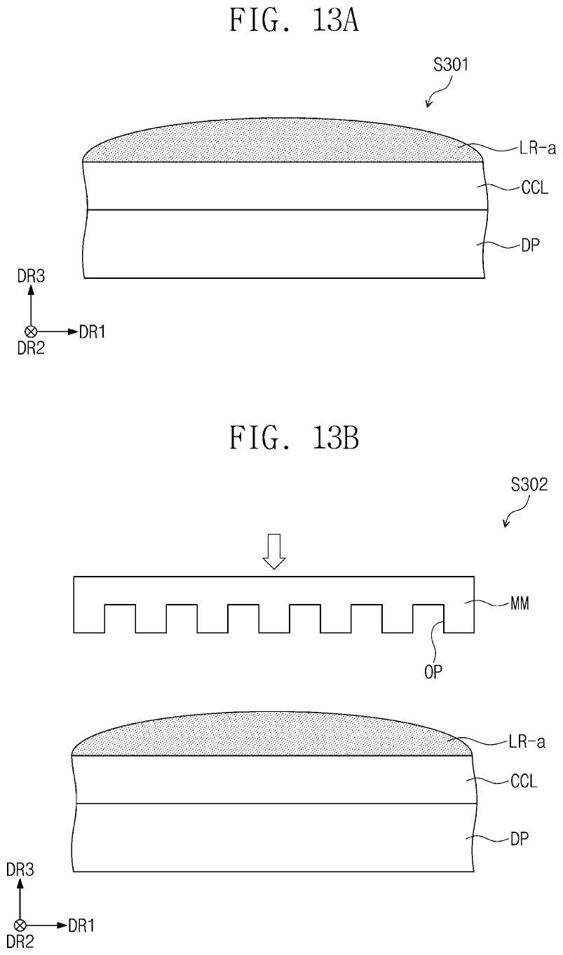

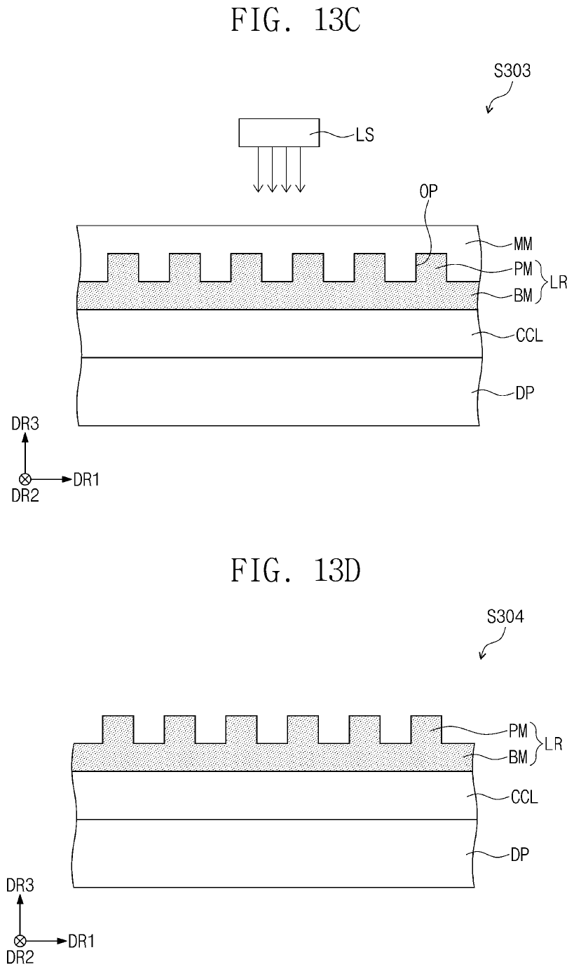

The content of the second color material may be greater than the content of the first color material in the low reflection layer composition LR-a (refer to FIG. 13A). For example, the content of the first color material may be equal to or greater than about 2% and equal to or smaller than about 50% of the content of the second color material.

The molar extinction coefficient of the second color material may be greater than the molar extinction coefficient of the first color material. For example, the molar extinction coefficient of the first color material is equal to or greater than about 10³ M⁻¹ cm⁻¹ and smaller than about 10⁵ M⁻¹ cm⁻¹, and the molar extinction coefficient of the second color material is equal to or greater than about 10⁵ M⁻¹ cm⁻¹.

The maximum absorption wavelength range of the second color material may be narrower than the maximum absorption wavelength range of the first color material. For example, the maximum absorption wavelength range of the first color material may be equal to or greater than about 500 nm and equal to or smaller than about 650 nm, and the maximum absorption wavelength range of the second color material may be equal to or greater than about 550 nm and equal to or smaller than about 630 nm.

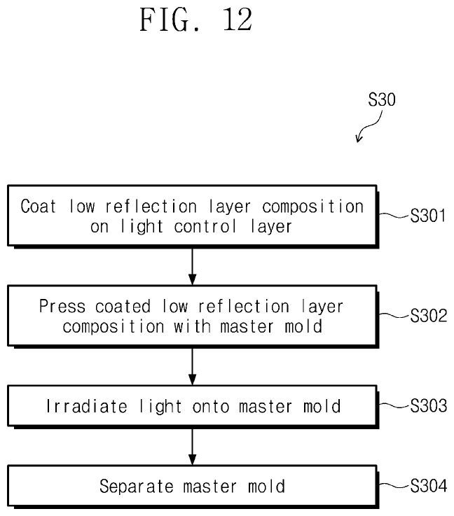

FIG. 12 is a flowchart showing a process of providing the low reflection layer (S30) of the manufacturing method of the display device according to an embodiment. FIGS. 13A to 13D are schematic cross-sectional views illustrating the processes of the manufacturing method of the display device. Providing the low reflection layer may include coating the low reflection layer composition (S301), pressing the coated low reflection layer composition with a master mold (S302), irradiating a light onto the master mold (S303), and separating the master mold (S304).

FIG. 13A is a schematic cross-sectional view showing the coating of the low reflection layer composition LR-a on the light control layer CCL. The low reflection layer composition LR-a may be coated on the light control layer CCL to form the low reflection layer LR (refer to FIG. 13D). The low reflection layer composition LR-a may include a base resin, a first color material, and a second color material. The base resin may be a light-curable resin.

The content of the first and second color materials included in the low reflection layer composition LR-a may be equal to or greater than about 0.2% or equal to or smaller than about 5% of the total content of the low reflection layer composition. Improving the color reproduction range and reducing the reflectance of the external light may be achieved by adjusting the content of the first and second color materials without lowering the light efficiency of the display device.

The low reflection layer composition LR-a may further include a release agent to easily remove the master mold, a photoinitiator to initiate a photocuring reaction, and/or a spread control material to prevent the low reflection layer composition LR-a from spreading and flowing.

FIG. 13B is a schematic cross-sectional view showing the process of pressing the low reflection layer composition LR-a with the master mold MM. The master mold MM may be provided on the coated low reflection layer composition LR-a and may be pressed toward the low reflection layer composition LR-a.

The master mold MM may have a shape that varies depending on the shape of the low reflection layer LR to be formed. When the low reflection layer LR includes the protrusions PM, the master mold MM may have grooves OP defined to correspond to the protrusions PM. The master mold MM may provide a mold to form the low reflection layer LR. When the coated low reflection layer composition LR-a is pressed by the master mold MM, the grooves OP of the master mold MM may be filled with the low reflection layer composition LR-a.

The master mold MM may include the light curable resin. It may be more economical to use a master mold MM including the light curable resin than to reuse a silicon wafer master mold repeatedly.

FIG. 13C is a schematic cross-sectional view showing the process of irradiating light onto the master mold MM to form the low reflection layer LR. When the light from light source LS is irradiated onto the master mold MM after pressing the master mold MM, the low reflection layer composition LR-a may be cured by the light. The low reflection layer LR may be formed when the low reflection layer composition LR-a is cured. The light irradiated onto the master mold MM may be an ultraviolet light.

The low reflection layer LR may include the base portion BM and the protrusions PM that protrude from the base portion BM, which are formed by the shape of the master mold MM. The low reflection layer LR may be patterned through the pressing of the master mold MM and the irradiating of the light. The low reflection layer LR formed through the providing of the low reflection layer according to the embodiment may include the protrusions PM arranged at regular intervals to form the pattern.

FIG. 13D is a cross-sectional view showing process of the separating of the master mold MM. As the master mold MM is separated from the low reflection layer LR, the display device DD according to the embodiments may be manufactured. When the release agent is further added to the low reflection layer composition LR-a, the master mold MM may be more easily separated.

Although not shown in FIGS. 11 to 13D, the manufacturing method according to the embodiments may further include providing a light control auxiliary layer on the light control layer. The low reflection layer composition LR-a may be coated on the light control auxiliary layer. The low reflection layer may be provided on the light control auxiliary layer through the steps for providing the low reflection layer shown in FIG. 12.

The manufacturing method of the display device according to the embodiment shown in FIG. 11 includes providing a low reflection layer that improves the color reproduction range of the display device and reduces the reflectance of the external light, and thus, improves the reliability of the display device.

Providing the low reflection layer according to the embodiment shown in FIG. 12 may be performed in an environment of room temperature and pressure. There is no risk of damage to the display device due to a manufacturing environment, such as low temperature, high temperature, or high pressure. The low reflection layer according to the embodiments may be provided in a simple and economical manner.

The display device according to the embodiments may include a low reflection layer that includes multiple color materials having different functional groups, and improving the color reproduction range and the visibility of the display device against external light. The color material with a relatively wide maximum absorption wavelength range reduces reflectance over the wide wavelength range. The color material with the smaller maximum absorption wavelength range has the relatively larger molar extinction coefficient, and the relatively larger content. The transmittance of the light in the smaller wavelength range is reduced further, and the color reproduction range increased. In addition, as the low reflection layer includes protrusions that further reduce the reflectance of external light on the display device.

According to the manufacturing method in the embodiments, the display device with an improved color reproduction range and improved visibility against external light may be manufactured simply and economically in a room temperature and pressure environment using a master mold.

Although the embodiments of the disclosure have been described, it is understood that the disclosure should not be limited to these embodiments but various changes and modifications can be made by one ordinary skilled in the art within the spirit and scope of the disclosure as hereinafter claimed.

Therefore, the disclosed subject matter should not be limited to any single embodiment described herein, and the scope of the inventive concept shall be determined according to the attached claims.

What is claimed is:

1. A display device comprising:
a display panel;
a light control layer disposed on the display panel; and
a low reflection layer disposed on the light control layer, the low reflection layer comprising:
a first color material having a first molar extinction coefficient; and
a second color material having a second molar extinction coefficient, a functional group of the second color material being different from a functional group of the first color material, wherein
the first molar extinction coefficient is smaller than the second molar extinction coefficient, and
a content of the first color material is smaller than a content of the second color material.

2. The display device of claim 1, wherein
the first molar extinction coefficient is equal to or greater than about 10³ M⁻¹ cm⁻¹ and smaller than about 10⁵ M⁻¹ cm⁻¹, and
the second molar extinction coefficient is equal to or greater than about 10⁵ M⁻¹ cm⁻¹.

3. The display device of claim 1, wherein
a maximum absorption wavelength range of the first color material is equal to or greater than about 500 nm and equal to or smaller than about 650 nm, and
a maximum absorption wavelength range of the second color material is equal to or greater than about 550 nm and equal to or smaller than about 630 nm.

4. The display device of claim 1, wherein the content of the first color material is equal to or greater than about 2% and equal to or smaller than about 50% of the content of the second color material.

5. The display device of claim 2, wherein at least one of the first color material and the second color material includes compounds with a same functional group but different substituents.

6. The display device of claim 1, wherein the low reflection layer comprises:
a base portion; and
protrusions protruding from the base portion and spaced apart from each other.

7. The display device of claim 6, wherein each of the protrusions has a width equal to or greater than about 10 nm and equal to or smaller than about 200 nm, and a height equal to or greater than about 10 nm and equal to or smaller than about 200 nm.

8. The display device of claim 6, wherein a shortest distance between adjacent ones of the protrusions is equal to or greater than about 10 nm and equal to or smaller than about 200 nm.

9. The display device of claim 6, wherein each of the protrusions has at least one of upward convex shape with a curved surface, a hemi-spherical shape, a cylindrical shape, and a prismatic shape.

10. The display device of claim 1, further comprising a light control auxiliary layer disposed between the light control layer and the low reflection layer, the light control auxiliary layer comprising:
a transflective layer; and
a phase control layer disposed on the transflective layer.

11. The display device of claim 10, wherein the transflective layer comprises a metal layer.

12. The display device of claim 10, wherein the phase control layer comprises at least one inorganic layer.

13. The display device of claim 1, wherein the display panel is flexible.

14. A display device comprising:
a display panel;
a light control layer disposed on the display panel; and
a low reflection layer disposed on the light control layer, the low reflection layer comprising:
a first color material including one or more compounds; and
a second color material including one or more compounds, wherein
the first color material comprises at least one of an anthraquinone-based compound, a phthalocyanine-based compound, and an azo-based compound, and
the second color material comprises at least one of a tetraazaporphyrin-based compound, a porphyrin-based compound, a squarylium-based compound, and a cyanine-based compound.

15. The display device of claim 14, wherein
the first color material has a molar extinction coefficient equal to or greater than about 10³ M⁻¹ cm⁻¹ and smaller than about 10⁵ M⁻¹ cm⁻¹,
the second color material has a molar extinction coefficient equal to or greater than about 10⁵ M⁻¹ cm⁻¹,
a maximum absorption wavelength range of the first color material is equal to or greater than about 500 nm and equal to or smaller than about 650 nm, and
a maximum absorption wavelength range of the second color material is equal to or greater than about 550 nm and equal to or smaller than about 630 nm.

16. The display device of claim 14, wherein a content of the first color material is equal to or greater than about 2% and equal to or smaller than about 50% of a content of the second color material.

17. The display device of claim 14, wherein the low reflection layer comprises:
a base portion; and
protrusions disposed on the base portion and spaced apart from each other.

18. A method of manufacturing a display device, comprising:
providing a display panel;
providing a light control layer on the display panel; and
providing a low reflection layer on the light control layer, wherein
the providing of the low reflection layer comprises providing a low reflection layer composition comprising a base resin, a first color material, and a second color material;
a content of the second color material is greater than a content of the first color material,
a molar extinction coefficient of the second color material is greater than a molar extinction coefficient of the first color material, and
a maximum absorption wavelength range of the second color material is smaller than a maximum absorption wavelength range of the first color material.

19. The method of claim 18, wherein the providing of the low reflection layer comprises:
coating the low reflection layer composition on the light control layer;
pressing the coated low reflection layer composition using a master mold;
irradiating a light onto the master mold to form the low reflection layer; and
separating the master mold.

20. The method of claim 18, wherein
a sum of the content of the first color material and the content of the second color material is equal to or greater than about 0.2% or equal to or smaller than about 5% of a total content of the low reflection layer composition, and
the content of the first color material is equal to or greater than about 2% and equal to or smaller than about 50% of the content of the second color material.
